(19) United States
(12) Patent Application Publication
(10) Pub. No.: US 2014/0238302 A1
(43) Pub. Date: Aug. 28, 2014

(54) APPARATUS FOR DEPOSITING ATOMIC LAYER

(71) Applicant: Samsung Electronics Co., Ltd., Suwon-Si (KR)

(72) Inventors: Ki Hyun KIM, Yongin-si (KR); Yeon Tae KIM, Hwaseong-si (KR); Nam Jin CHO, Suwon-si (KR)

(73) Assignee: SAMSUNG ELECTRONICS CO., LTD., Suwon-Si (KR)

(21) Appl. No.: 14/182,407

(22) Filed: Feb. 18, 2014

(30) Foreign Application Priority Data
Feb. 27, 2013 (KR) 10-2013-0021090

(51) Int. Cl. C23C 16/52

(52) U.S. Cl. CPC C23C 16/52
USPC 118/724

(57) ABSTRACT

An atomic layer deposition apparatus including a substrate loading unit provided in a process chamber, the substrate loading unit including at least one substrate loading plate on which a substrate is to be loaded, an injector assembly coupled to the process chamber and configured to supply a plurality of reactants to deposit a multilayer film onto the substrate while sweeping over the substrate loaded on the substrate loading plate, a plurality of first heat sources configured to heat in a non-contact manner, and, a plurality of second heat sources configured to heat in a contact manner, the first and second heat sources at different positions in the process chamber may be provided.

### CROSS-REFERENCE TO RELATED APPLICATIONS

This application claims the benefit of Korean Patent Application No. 10-2013-0021090, filed on Feb. 27, 2013, in the Korean Intellectual Property Office, the disclosure of which is incorporated herein in its entirety by reference.

### BACKGROUND

The inventive concepts relate to apparatuses for depositing an atomic layer, and more particularly, to atomic layer deposition apparatuses capable of controlling a process temperature according to the type of a reactant during deposition of a multilayer film.

With high integration of a semiconductor device, there has been a continuing demand for a thin film deposition process that can precisely control a thickness of a film at or under a nano scale. Accordingly, more advanced thin film deposition technologies than a physical vapor deposition (PVD) technology or a chemical vapor deposition (CVD) technology has been researched. An atomic layer deposition technology is one of the technologies satisfying such a demand.

The atomic layer deposition technology was introduced by Suntola of Finland in mid-seventies under the name of an atomic layer epitaxy technology. Initially, the atomic layer deposition technology was applied to deposition of a fluorescent layer thin film of an electro-luminescent flat panel display device. Recently, the atomic layer deposition technology has been widely researched and developed to be applied to a semiconductor manufacturing process.

The atomic layer deposition technology is a new concept of a thin film deposition technology in which reaction precursors are individually separated to flow on a semiconductor substrate in the form of pulses and thus chemisorption and desorption due to saturated surface reaction of a reactant on a surface of the semiconductor substrate are used.

According to the atomic layer deposition technology, a reactant A is supplied to a surface of substrate and chemically adsorbed through a reaction with the surface of the substrate. When an atomic layer of the reactant A is deposited, an excess of the reactant A is removed. Then, a reactant B is supplied in the same manner so that an atomic layer of the reactant B is deposited on the atomic layer surface of the reactant A, thereby growing an atomic layer thin film. An apparatus where the atomic layer deposition technology is embodied is referred to as an atomic layer deposition apparatus.

To properly perform an atomic layer deposition, an atomic layer deposition apparatus should satisfy, for instance, the conditions during an atomic layer deposition process discussed below.

First, a reaction between a reactant and a surface of a substrate should be a self-limiting reaction.

Second, the self-limiting reaction or a chemisorption should be a main reaction. The self-limiting reaction means that a reaction occurs only between the reactant and the substrate surface, not between the reactants.

Recently, the desired deposition thickness of a thin film gradually decreases lower than 100 Å due to ultra-fineness of a semiconductor device. Accordingly, the atomic layer deposition technology is facing challenges in obtaining an ultra-thin film having desired electrical characteristics.

In order to obtain desired electrical characteristics in an ultra-thin film having a deposition thickness of 100 Å or less, a method of depositing a multilayer film (e.g., a dual layer film or a triple layer film rather than a mono layer film) on a substrate has been suggested. However, depositing multilayer film on a substrate by using a conventional atomic layer deposition apparatus has not been put into actual use due to some technical challenges.

As described above, in an atomic layer deposition process, the chemisorption by a self-limiting reaction is a main reaction, and temperature ranges at which a self-limiting reaction is performed are different according to reactants. Accordingly, when two or more reactants having different temperature ranges are used to deposit a thin film, a chemisorption by a self-limiting reaction may not be properly performed and thus electrical characteristics of a thin film may not be optimized.

### SUMMARY

An aspect of the inventive concepts provide atomic layer deposition apparatuses that may optimize electrical characteristics of a thin film by properly performing a chemisorption by a self-limiting reaction, which is achieved by flexibly adjusting process temperatures with respect to respective reactants during deposition of a multilayer film.

According to one example embodiment, an atomic layer deposition apparatus includes a substrate loading unit provided in a process chamber, which includes at least one substrate loading plate on which a substrate is loaded, an injector assembly coupled to the process chamber and configured to supply a plurality of reactants to deposit a multilayer film onto the substrate while sweeping over the substrate loaded on the substrate loading plate, and a plurality of heat sources at different positions in the process chamber, a plurality of first heat sources configured to heat in a non-contact manner, and a plurality of second heat sources configured to heat in a contact manner, the first and second heat sources at different positions in the process chamber.

The atomic layer deposition apparatus may further include a controller configured to control the first and second heat sources to ensure chemisorption by a self-limiting reaction with respect to each one of the reactants at a respective process temperature thereof.

When any one of the reactants is supplied into the process chamber, the controller may be configured to control the first and second heat sources in real time such that the process temperature in the process chamber corresponds to the process temperature of the reactant supplied into the process chamber.

The substrate loading plate may be a plurality of substrate loading plates, which are arranged in a vertical direction in the process chamber, and are configured to move up and down in the vertical direction in the process chamber.

The first and second heat sources may be provided with respect to the substrate loading plates.

The first heat sources may be configured to contact and heat the substrate. The second heat sources may be adjacent to the first heat source and be configured to heat the substrate in a non-contact manner.

The first heat sources and the second heat sources may be configured to be independently controlled.

The first heat sources may be heating pads. Each of the heating pads may be attached on an upper surface of the substrate loading plate and be configured to directly contact the substrate.

The second heat sources maybe arranged on at least one side wall surface of the process chamber at an outer area of a circumferential surface of the substrate loading plate.

The second heat sources may be symmetrically arranged with respect to the substrate loading plate at the opposite side wall surfaces of the process chamber.

The atomic layer deposition apparatus may further include a source accommodation portion that is formed on the side wall surface of the process chamber and configured to accommodate the second heat source.

The atomic layer deposition apparatus may further include a protection window provided between the substrate loading unit and the source accommodation portion and configured to protect the second heat sources, and a heat reflection mirror provided between the protection window the side wall surface of the process chamber, the heat reflection mirror configured to reflect heat generated from the second heat sources while maintaining directivity.

The protection window may include a flat surface and the heat reflection mirror may include a curved surface.

The second heat sources may be respectively arranged above and parallel to the substrate loading plate.

The injector assembly may include a plurality of vertical shafts arranged at respective corner areas of the process chamber and the vertical shafts arranged at diagonal positions forming an operational group, a plurality of injectors arranged on the vertical shafts, each of which is arranged at a certain interval along a lengthwise direction of a corresponding one of the vertical shafts and configured to selectively supply the reactants through a plurality of injection holes defined in the injector, and a plurality of shaft rotation units coupled to the vertical shafts and configured to rotate the vertical shafts.

The injectors may be configured to selectively inject the reactants onto the substrate while sweeping over the substrate in association with rotation of corresponding vertical shafts.

The atomic layer deposition apparatus may further include a controller configured to control operation of the first and second heat sources based on the reactants supplied to the process chamber.

In one example embodiment, an atomic layer deposition apparatus include a plurality of first heat sources and a plurality of second heat sources arranged at various positions in a process chamber, the first heat sources configured to heat at least one substrate in the process chamber in a non-contact manner, and the second heat sources configured to heat the substrate in a contact manner, an injector assembly configured to selectively supply a reactant from a plurality of reactants to the process chamber, and a controller configured to control the first and second heat sources based on the supplied reactant.

The injector assembly may be configured to selectively inject one of the reactants onto the substrate loaded on the substrate loading plate while sweeping over the substrate.

The injector assembly may include a plurality of injectors coupled to each of a plurality of vertical shafts, each of the injectors arranged at a certain interval along a lengthwise direction of the corresponding one of the vertical shafts and configured to selectively supply the reactants through a plurality of injection holes defined in the injector, and a plurality of shaft rotation units coupled to the vertical shafts, the shaft rotation units configured to simultaneously rotate an operational group of the injectors by rotating the vertical shafts.

The injector assembly may include a plurality of injectors coupled to plurality of vertical shafts, and each of the injectors are configured to selectively inject the reactants onto the substrate while sweeping over the substrate in association with rotation of one of the vertical shafts.

### BRIEF DESCRIPTION OF THE DRAWINGS

Example embodiments of the inventive concepts will be more clearly understood from the following detailed description taken in conjunction with the accompanying drawings in which:

FIG. 1 is a conceptual view illustrating a cycle of an atomic layer deposition process;

FIG. 2 is a graph for explaining a relationship between deposition and a process temperature according to reactants;

FIG. 3 is a perspective view of an atomic layer deposition apparatus according to an example embodiment of the inventive concepts;

FIG. 4 is a plan view of FIG. 3;

FIG. 5 is a partially cut-away perspective view of FIG. 3;

FIG. 6 is an enlarged view of a portion B of FIG. 5;

FIG. 7 is a front view of FIG. 5;

FIG. 8 illustrates a state in which an injector is swept in FIG. 7;

FIG. 9 is an enlarged view of a portion C of FIG. 8 in which a substrate is arranged;

FIG. 10 illustrates a sweeping operation of the injector;

FIG. 11 is a block diagram illustrating a control operation of the atomic layer deposition apparatus of FIG. 1;

FIG. 12 is a partially cut-away perspective view of an atomic layer deposition apparatus according to another example embodiment of the inventive concepts;

FIG. 13 is a front view of FIGS. 12; and

FIG. 14 illustrates a state in which the injector is swept in FIG. 13.

### DETAILED DESCRIPTION OF EXAMPLE EMBODIMENTS

The attached drawings for illustrating example embodiments of the inventive concepts are referred to in order to gain a sufficient understanding of the inventive concepts and the merits thereof. Hereinafter, example embodiment will be described in detail by explaining some example embodiments of the inventive concepts with reference to the attached drawings. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

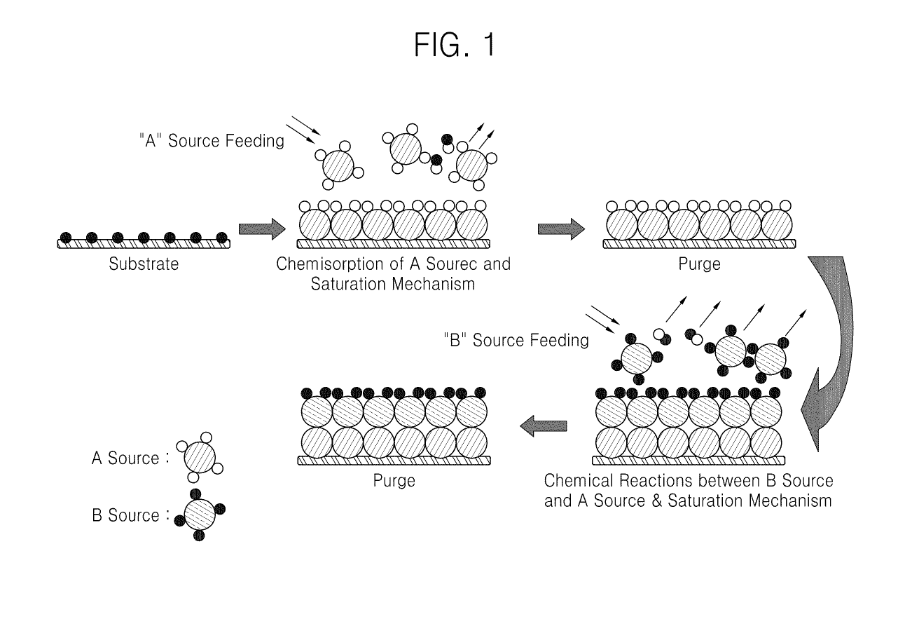

FIG. 1 is a conceptual view illustrating a cycle of an atomic layer deposition process. According to an example embodiment, an atomic layer deposition apparatus may perform a deposition process according to the cycle illustrated in FIG. 1. As an example, FIG. 1 illustrates a case where two sources, i.e., source A and source B, are used.

Operation 1: Source A (first gas)is supplied into a reaction chamber of an atomic layer deposition apparatus. The source A undergoes a chemisorption with a surface of a substrate. Accordingly, a first atomic layer by the source A is deposited on the substrate surface. Even when the source A is continuously supplied, deposition reactions do not continue after the deposition by the source A is completed.

Operation 2: An excess of the source A is purged out of the reaction chamber by using an inert gas when the reaction chamber of an atomic layer deposition apparatus is in a state where the source A does not react any longer.

Operation 3: When the source A is completely purged out of the reaction chamber, source B (second gas) is supplied into the reaction chamber. The supplied source B undergoes a chemisorption with the source A in the first atomic layer that was previously attached to the substrate surface through a chemisorption. Accordingly, a second atomic layer by the source B is deposited on the first atomic layer. Even when the source B is continuously supplied, deposition reactions do not continue after the deposition by the source B is completed.

Operation 4: An excess of the source B is purged out of the reaction chamber by using an inert gas when the reaction chamber of an atomic layer deposition apparatus is in a state where the source B does not react any longer.

If another atomic layer by source C is to be further deposited on the atomic layer by the source B, the above-described method is performed in the same or similar manner.

The operations 1 through 4 form a cycle and, by repeating the cycle, an atomic layer thin film having a desired thickness may be grown (deposited) on a substrate. In order to grow an atomic layer thin film having a desired thickness on a substrate as described above, a chemisorption by a self-limiting reaction may be properly performed.

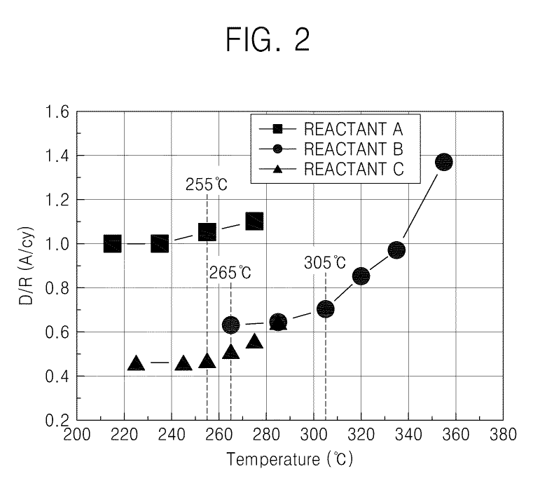

FIG. 2 is a graph for explaining a relationship between deposition and a process temperature according to reactants. In FIG. 2, a relationship between deposition rates and process temperatures with respect to reactant A, reactant B, and reactant C are shown when each one of the reactant A, the reactant B, and the reactant C are deposited on a substrate to form an atomic layer thin film.

As described above, to obtain electrical characteristics in an ultra-thin film having a deposition thickness of 100 Å or less, a multilayer film may be deposited on a substrate. However, when a process temperature varies with respect to respective reactants and is not properly controlled during deposition of a multilayer film, a chemisorption by a self-limiting reaction may not be properly performed.

When the reactant A is supplied into the process chamber, a process temperature may be maintained at a first temperature of, for example, 255° C., so that the reactant A may undergo a proper chemisorption by a self-limiting reaction.

However, when reactant B that has a totally different process temperature for a self-limiting reaction from the reactant A is supplied into the process chamber, the process temperature for a self-limiting reaction from the reactant B may be maintained accordingly at a second temperature of, for example, 265° C., for instance, simultaneously with the supply of the reactant B into the process chamber. Further, when reactant C is supplied into the process chamber, the process temperature for a self-limiting reaction from the reactant C may be maintained at a third temperature, which is different from the first and second temperatures, for instance, simultaneously with the supply of the reactant C into the process chamber.

By maintaining different temperatures with respect to respective reactants A, B, and C, chemisorptions by self-limiting reactions of each reactant may be properly performed. Accordingly, electrical characteristics of a thin film may be optimized while reducing impurities or defects in the thin film, for example.

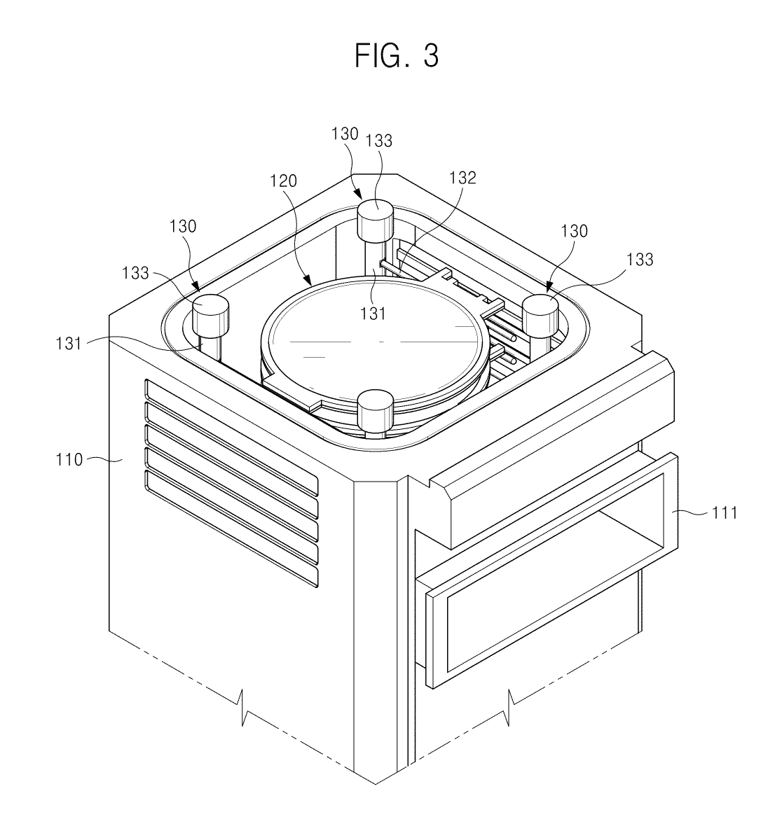

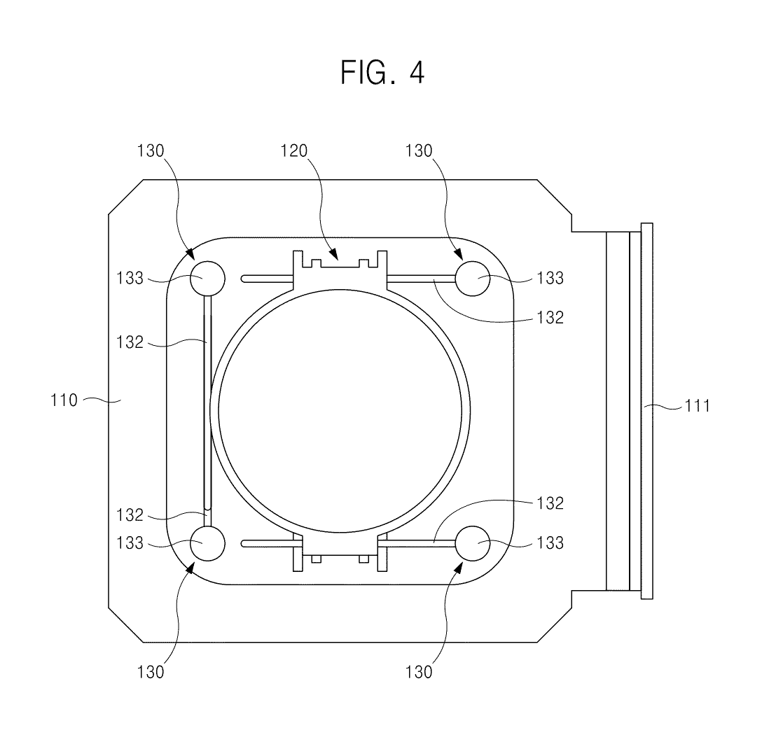

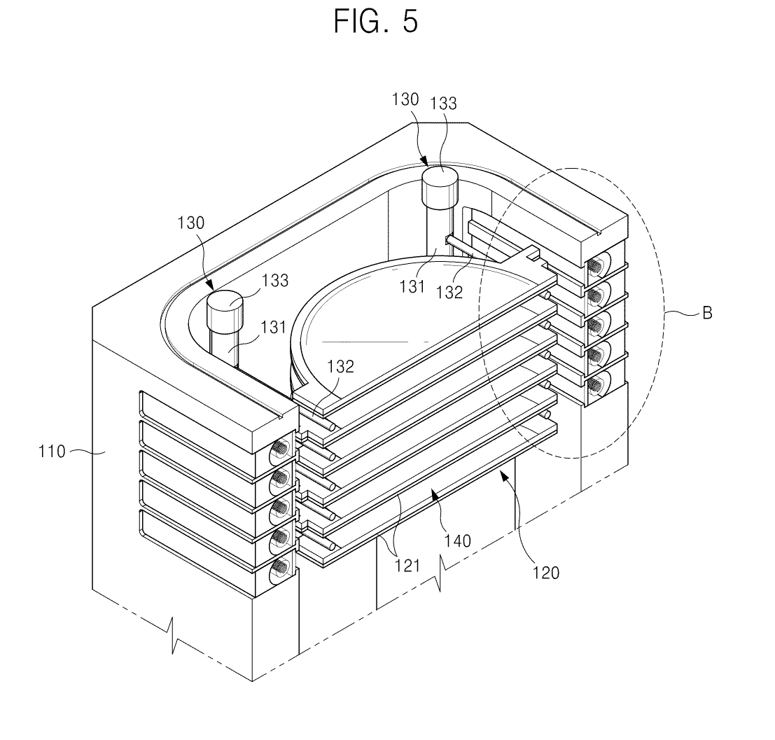

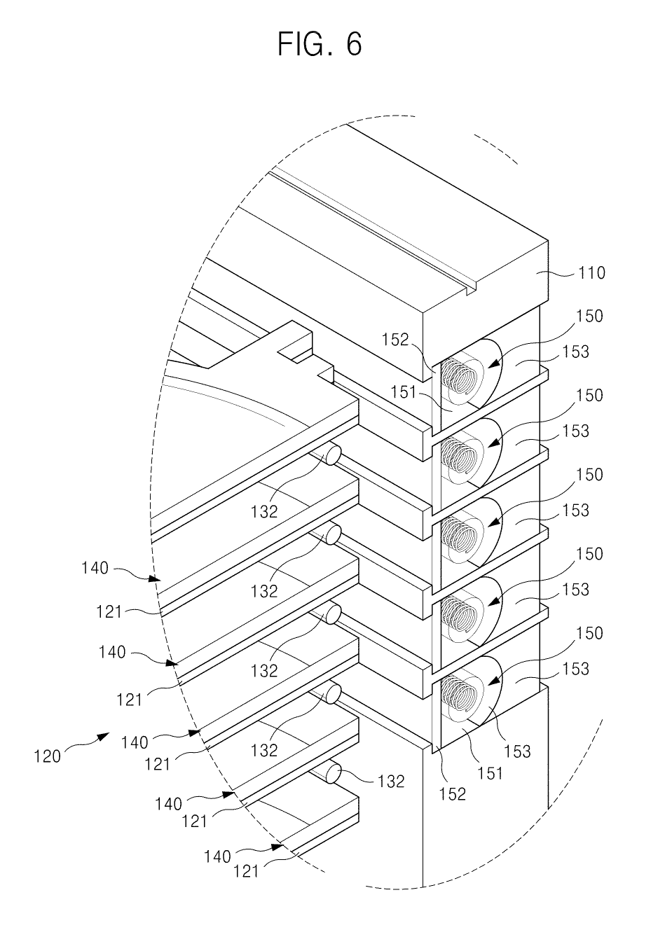

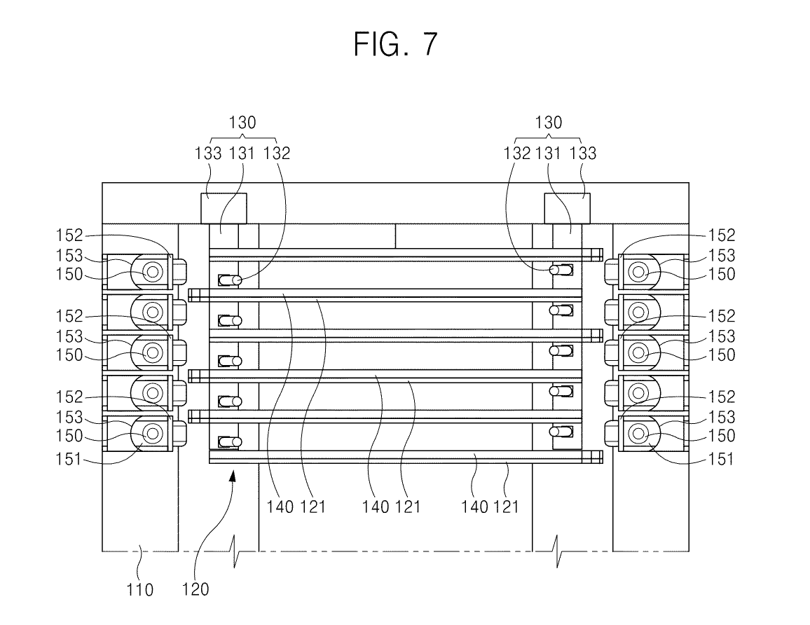

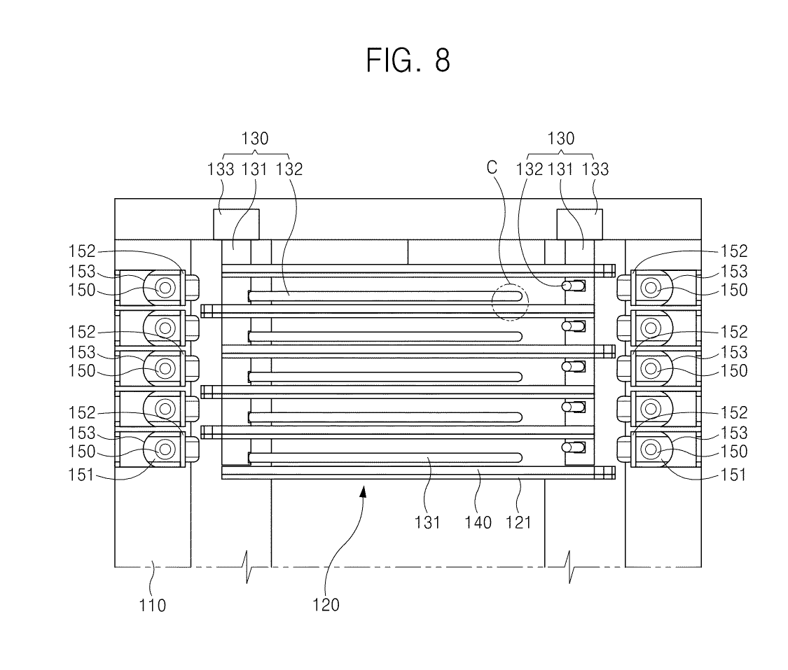

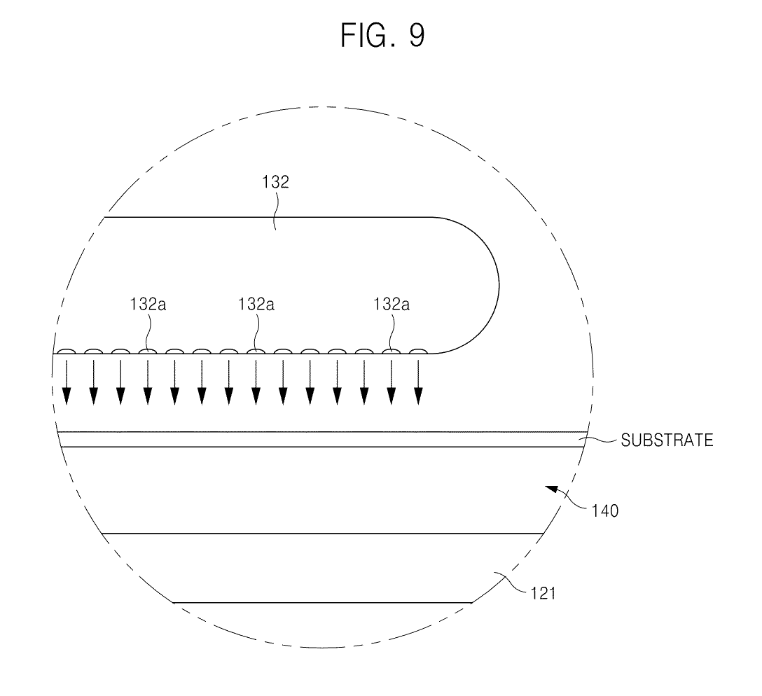

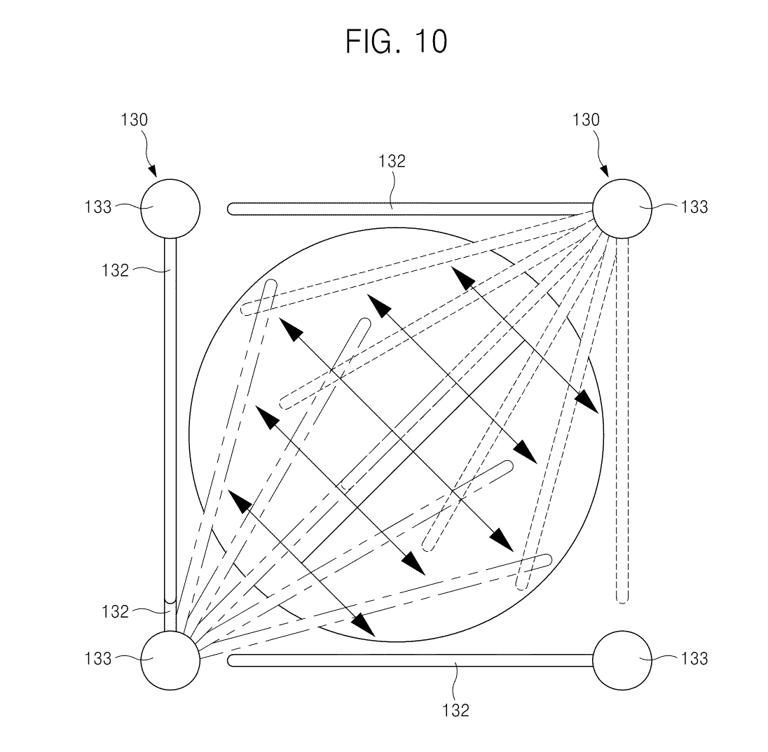

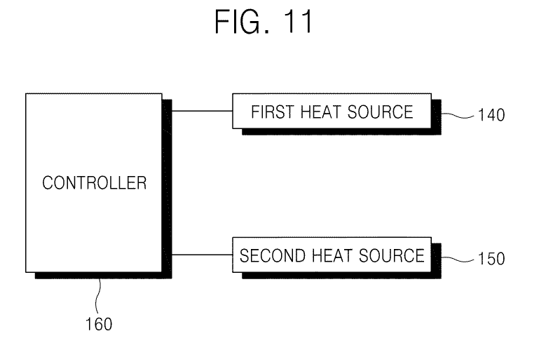

FIG. 3 is a perspective view of an atomic layer deposition apparatus according to an example embodiment. FIG. 4 is a plan view of FIG. 3. FIG. 5 is a partially cut-away perspective view of FIG. 3. FIG. 6 is an enlarged view of a portion B of FIG. 5. FIG. 7 is a front view of FIG. 5. FIG. 8 illustrates a state in which an injector is swept in FIG. 7. FIG. 9 is an enlarged view of a portion C of FIG. 8 in which a substrate is arranged. FIG. 10 illustrates a sweeping operation of the injector. FIG. 11 is a block diagram illustrating a control operation of the atomic layer deposition apparatus of FIG. 1.

Referring to FIGS. 3 through 11, an atomic layer deposition apparatus according to an example embodiment may appropriately control a process temperature according to reactants during deposition of a multilayer film. The atomic layer deposition apparatus may include a process chamber 110, a substrate loading unit 120, an injector assembly 130, multi heat sources 140 and 150, and a controller 160.

The atomic layer deposition apparatus according to the present embodiment may be applied to all fields needing thin film deposition, for example, a memory field, a non-memory field, a display field, an energy field, etc.

Referring to FIG. 3, the process chamber 110 is a place in which an atomic layer deposition process is performed by the method of FIG. 1 with respect to a substrate (e.g., a wafer). The process chamber 110 may form an independent space, which is hermetically sealed from the outside, for a smooth operation of an atomic layer deposition process.

An exhaust pipe (not shown) may be formed under the process chamber 110 and a vacuum pump (not shown) may be connected to the exhaust pipe. Air in the process chamber 110 may be pumped by the operation of the vacuum pump, and thus the inside of the process chamber 110 may be maintained in a low vacuum or high vacuum state.

Although it is not illustrated in detail, a plurality of process chambers may be arranged in a cluster type around a transfer chamber (not shown) for transferring a substrate, in which the process chambers may be connected to each other in a spreading-out manner. In the example embodiment, a robot in the transfer chamber may hold a substrate and transfer the substrate to the process chamber 110.

A gate 111 may be formed at one side of the process chamber 110, through which the robot may carry a substrate into the process chamber 110 to perform an atomic layer deposition process or may carry the substrate completed the atomic layer deposition process out of the process chamber 110. A gate valve configured to open gin or closing an opening of the gate 111 may be provided at the gate 111.

The substrate loading unit 120 may be provided in the process chamber 110 and include a substrate loading plate 121 on which the substrate is loaded. According to the example embodiment, the substrate loading plate 121 may have a multi-slot structure for performing a deposition process on a plurality of substrates at the same time. For example, the substrate loading plate 121 may be provided in multiple numbers, for example, 5, in a vertical direction in the process chamber 110. Thus, deposition processes may be simultaneously performed, for instance, on five substrates.

The substrate may be carried to and from the substrate loading plate 121 through the gate 111, and the substrate loading plates 121 maybe capable of moving up and down in the process chamber 110. For example, when the substrate is supplied, the substrate loading plates 121 may be arranged in a lower area of the process chamber 110. Then, when the substrate is loaded, the substrate loading plates 121 may move to an upper process position in the process chamber 110 and then a deposition process may be performed.

The injector assembly 130 may be coupled to the process chamber 110 and supply a plurality of reactants for the deposition of a multilayer film onto the substrate surface while sweeping over the substrate loaded on each of the substrate loading plates 121, as illustrated in FIGS. 7 to 10.

The injector assembly 130 may include a plurality of vertical shafts 131 arranged at the respective corner areas of the process chamber 110, a plurality of injectors 132 arranged on each of the vertical shafts 131 at a certain interval there between along the lengthwise direction thereof and supplying a plurality of reactants for the deposition of a multilayer film onto the substrate surface while sweeping over the substrate during the rotation of each of the vertical shafts 131, and a shaft rotation unit 133 coupled to each of the vertical shafts 131 to rotate the vertical shafts 131.

In the present example embodiment, the vertical shafts 131 may be respectively arranged at the corner areas of the process chamber 110. The shaft rotation unit 133, for example, a motor, may be coupled to the top end portion of each of the vertical shafts 131.

The injectors 132 may be arranged on each of the vertical shafts 131. The number of the injectors 132 may be as many as the number of the substrate loading plates 121. The injectors may be arranged at a certain interval along the lengthwise direction of the vertical shafts 131. The injectors 132 may perform a deposition process while sweeping over an upper surface of the substrate as illustrated in FIG. 10.

In the present example embodiment, a deposition process may be performed on all five substrates at once, and thus one vertical shaft 131 may be provided with five injectors 132. However, example embodiments are not limited to the above number. The injectors 132 may not be arranged in and/or around the gate 111.

In detail, in the injector assembly 130 according to the present example embodiment, because five injectors 132 may be connected to one vertical shaft 131, the five injectors 132 may simultaneously move tracing the same line during the rotation of the vertical shaft 131 by the shaft rotation unit 133.

As a result, reactant (gas) passing through the vertical shaft 131 may be injected onto the surfaces of five substrates through a plurality of injection holes 132a formed in the five injectors 132, thereby performing a deposition process.

The injectors 132 provided on each of the four vertical shafts 131 may inject the gaseous reactant while sweeping over the substrate. The injectors 132 arranged at one diagonal side may form one operational group as illustrated in FIG. 10.

The injectors 132 arranged at the opposite diagonal side with respect to the one diagonal side may form another operational group and inject another gaseous reactant that may react with the preceding reactant to sequentially perform a deposition process.

For example, the injectors 132 operating as indicated by a dotted line in FIG. 10 may inject gaseous reactant onto the substrate while sweeping over the substrate. The gaseous reactance may be tri methyl aluminum (TMA), dimethyl aluminum hydride (DMAH), dimethyl aluminum hydride ethyl piperidine (DMAHEPP), tetrakis ethylmethylamino hafnium (TEMAH), tetrakis diethylamino hafnium (TDEAH), tetrakis dimethylamino hafnium (TDMAH), tetrakis ethylmethylamino zirconium (TEMAZ), tetrakis diethylamino zirconium (TDEAZ), tetrakis dimethylamino zirconium (TDMAZ), silane, ammonia, etc.

The injectors 132 that do not operate in FIG. 10 may inject an oxidation reaction gas such as N₂O, NO, NO₂, and O₃ onto the substrate while sweeping over the substrate.

In such a manner, a pair of the injector assemblies 130 can inject reactant onto five sheets of substrates by one-time operation of sweeping (e.g., scanning), thereby achieving a higher throughput than existing equipment.

Also, in the example embodiment, because the four vertical shafts 131 may be provided with respect to each substrate, a replacement time of reactant may be short, and thus a reactant replacement time loss may be reduced compared to the existing equipment. Accordingly, a higher throughput may be achieved.

Further, the rotation speed of the vertical shaft 131 can be optimized through the control of the shaft rotation unit 133 in a way to enhance throughput.

The multi heat sources 140 and 150 may be arranged at a plurality of different positions in the process chamber 110 to heat the inside of the process chamber 110 corresponding to the process temperature that varies according to reactants.

When the multi heat sources 140 and 150 are employed as in the example embodiment, the process temperature that varies according to reactants may be flexibly changed to the process temperature corresponding to each reactant during the deposition of a multilayer film. Accordingly, the chemisorption by a self-limiting reaction may be properly performed and thus electrical characteristics of a thin film may be optimized.

The multi heat sources 140 and 150 may include a first heat source 140, which contacts and heats the substrate, and a second heat source 150, arranged adjacent to the first heat source 140, that heats the substrate in a non-contact manner.

In the example embodiment, the first and second heat sources 140 and 150 may be arranged with respect to each substrate loading plate 121. The controller 160 may simultaneously or independently control the first and second heat sources 140 and 150.

The first heat source 140 may be a heating pad that is attached on an upper surface of the substrate loading plate 121 and configured to directly contact a loaded substrate. The second heat source 150 may be arranged on a side wall surface of the process chamber 110, e.g., at an outer area of a circumferential surface of the substrate loading plate 121. The second heat sources 150 may be symmetrically arranged with respect to the substrate loading plate 121 at the opposite side wall surfaces of the process chamber 110. According to a different example embodiment, the second heat source 150 may be provided inside or outside the process chamber 110 or may be incorporated in the process chamber 110. As a result, the second heat source 150 may be arranged on all surfaces or space of the process chamber 110.

In the example embodiment, the second heat source 150 may be, e.g., a resistive heater, a lamp heater, or a combination thereof. The second heat source 150 may be formed of all non-metal materials including quartz and a metal material including aluminum. A heat transfer method of the second heat source 150 may be any of conduction, convection, radiation, etc.

In the example embodiment, although the second heat source 150 is arranged on the side wall surface of the process chamber 110 and performs heat transfer roughly in a horizontal direction, the heat may be transferred in a vertical or inclined direction.

To install the second heat source 150, a source accommodation portion 151 for accommodating the second heat source 150 may be formed on the side wall surface of the process chamber 110. A protection window 152 for protecting the second heat source 150 may be provided between the substrate loading unit 120 and the source accommodation portion 151. A heat reflection mirror 153 for reflecting heat generated from the second heat source 150 while maintaining directivity may be provided between a protection window and the side wall surface of the process chamber 110. As illustrated in the drawings, the protection window 152 may have a flat surface, whereas the heat reflection mirror 152 may have a curved surface.

The controller 160 may control the first and second heat sources 140 and 150 such that a plurality of reactants may perform chemisorptions by self-limiting reactions at process temperatures corresponding to the reactants. The controller 160 may control in real time the first and second heat sources 140 and 150 such that, when any one of the reactants is supplied into the process chamber 110, the process temperature of the inside of the process chamber 110 may correspond to the process temperature of the reactant supplied into the process chamber 110.

The operation of the atomic layer deposition apparatus configured as above is described below.

For example, five sheets of substrates may be carried by a separate robot into the process chamber 110 and loaded onto a plurality of the substrate loading plates 121. When the substrates are supplied, the substrate loading plates 121 may be positioned in a lower area of the process chamber 110. As the substrates are loaded on the substrate loading plates 121, the substrate loading plates 121 may be moved up to an upper process position in the process chamber 110 and then a deposition process may begin.

For example, when a deposition process of reactant A begins, the controller 160 may simultaneously or independently control the first and/or second heat sources 140 and 150 in real time. For example, the controller 160 may simultaneously or independently control the first and/or second heat sources 140 and 150 in real time so that the reactant A may undergo a proper chemisorption by a self-limiting reaction, while the controller 160 controls in real time the first and/or second heat sources 140 and 150 to maintain the process temperature at 255° C., for example.

The shaft rotation unit 133 may rotate the vertical shaft 131 and accordingly the five injectors 132 may move above the respective substrates simultaneously tracing the same line. Thus, the reactant (gas) input through the vertical shaft 131 may be respectively injected onto the surfaces of the five substrates through the injection holes 132a formed in the five injectors 132, thereby performing an atomic layer deposition process with the reaction A. The detailed cycle of the atomic layer deposition process is described above with reference to FIG. 1.

Next, when the atomic layer deposition process using the reactant A is completed, an atomic layer deposition process using reactant B may begin. When the reactant B is supplied into the process chamber 110, because the reactant B has a different process temperature of a self-limiting reaction from the reactant A, the process temperature may change to, for example, 265° C. as soon as the reactant B starts to be supplied into the process chamber 110. This temperature change is controlled by the controller 160.

For example, while the controller 160 simultaneously or independently controls the first and/or second heat sources 140 and 150 in real time, the controller 160 may control in real time the first and/or second heat sources 140 and 150 to maintain the process temperature at 265° C., for example, so that the reactant B may undergo a proper chemisorption by a self-limiting reaction.

When the process temperature is set to a temperature at which the reactant B may undergo a proper chemisorption by a self-limiting reaction, an atomic layer deposition process using the reactant B may be performed by the operations of the injectors 132.

When the atomic layer deposition process using the reactant B is completed, an atomic layer deposition process using reactant C may begin in the same or similar manner as described above with respect to reactants A and/or B.

According to the example embodiments illustrated above, during deposition of a multilayer film, the electrical characteristics of a thin film may be optimized by properly performing a chemisorption by a self-limiting reaction. The chemisorption by a self-limiting reaction may be properly performed by flexibly adjusting process temperatures with respect to respective reactants.

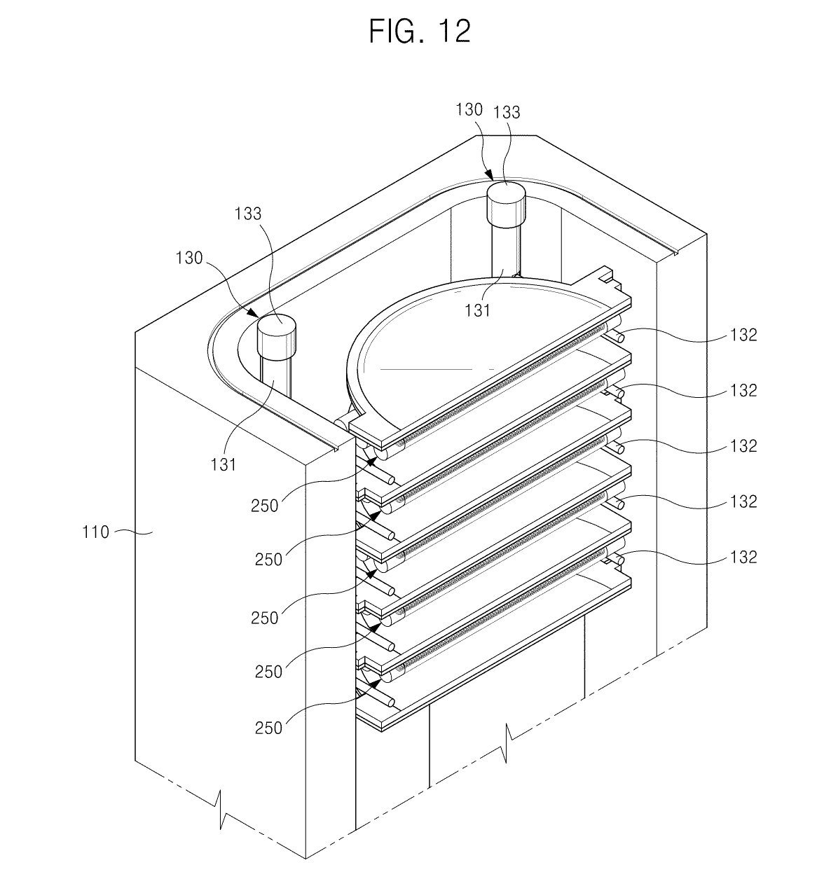

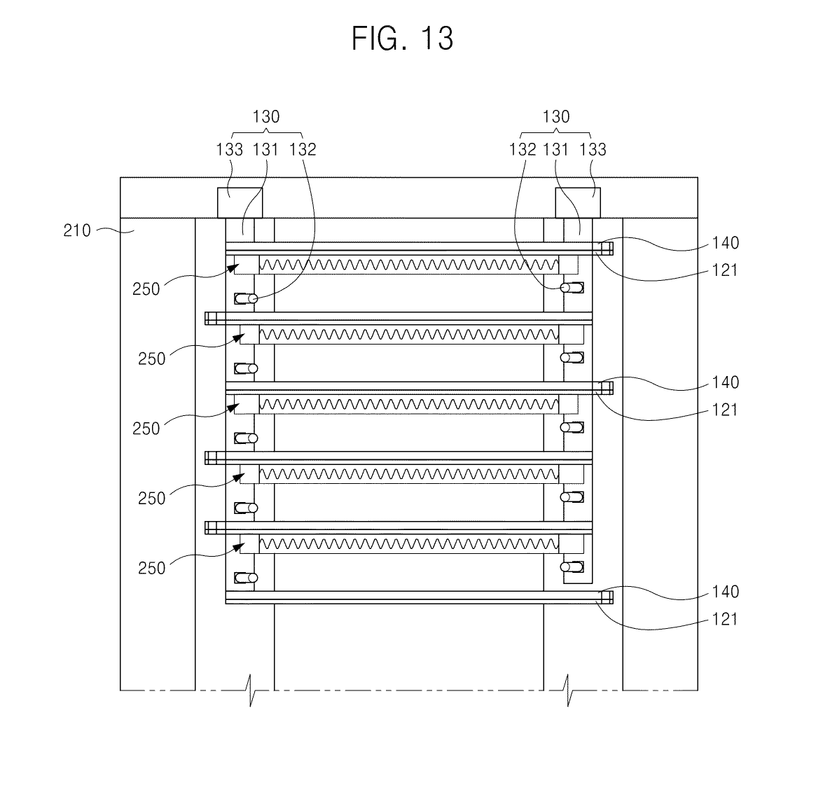

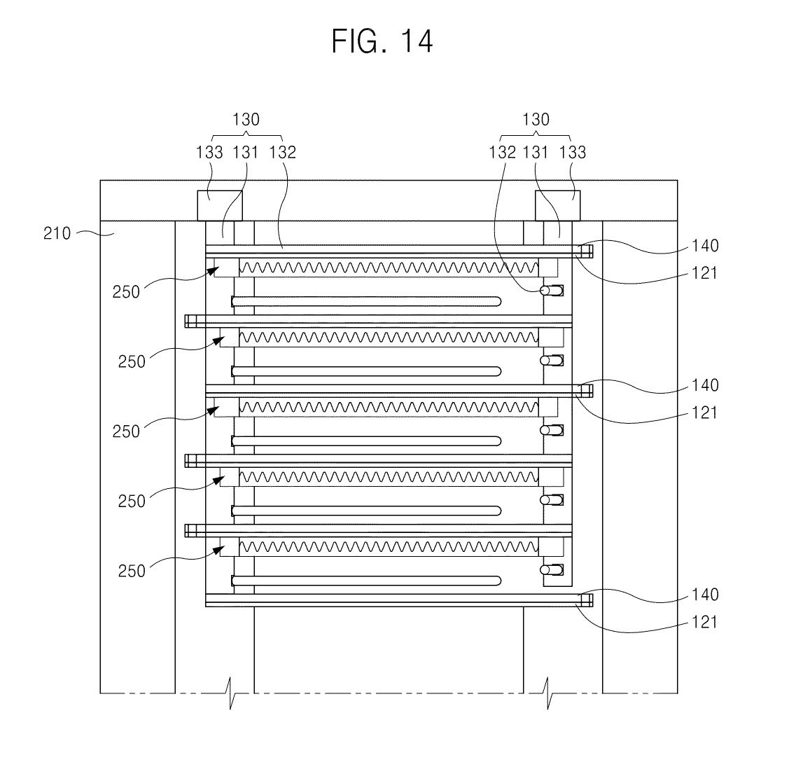

FIG. 12 is a partially cut-away perspective view of an atomic layer deposition apparatus according to another example embodiment of the inventive concepts. FIG. 13 is a front view of FIG. 12. FIG. 14 illustrates a state in which the injector is swept in FIG. 13.

In the example embodiment, a second heat source 250 may be arranged above the substrate loading plates 121 to be parallel to the substrate loading plate 121. Thus, although the second heat source 150 according to the previous example embodiment may be arranged on the side wall surface of the process chamber 110 to transfer heat in a horizontal direction, the second heat source 250 according to this example embodiment may be arranged above the substrate loading plate 121 to transfer heat in a vertical direction.

In the above structure, during the deposition of a multilayer film, the electrical characteristics of a thin film may be optimized by properly performing a chemisorption by a self-limiting reaction. The chemisorption by a self-limiting reaction may be properly performed by flexibly adjusting process temperatures with respect to respective reactants.

In the example embodiment, the second heat source 250 may be arranged with respect to each substrate loading plate 121, or a plurality of the second heat sources 250 may be arranged on to each substrate loading plate 121.

In the example embodiment, the second heat source 250 may be, e.g., a resistive heater, a lamp heater, or a combination thereof. The second heat source 250 may be formed of all non-metal materials including quartz and a metal material including aluminum. A heat transfer method of the second heat source 250 may be any of conduction, convection, radiation, etc. The structures and functions of the other constituent elements are the same as those in the above-described example embodiments.

As described above, according to the present inventive concept, during the deposition of a multilayer film, the electrical characteristics of a thin film may be optimized by properly preforming a chemisorption by a self-limiting reaction. The chemisorption by a self-limiting reaction may be properly performed by flexibly adjusting process temperatures with respect to respective reactants.

While some example embodiment have been particularly shown and described above, it will be understood by one of ordinary skill in the art that various changes in form and details may be made therein without departing from the spirit and scope of example embodiments defined by the following claims.

What is claimed is:

1. An atomic layer deposition apparatus comprising:
a substrate loading unit in a process chamber, the substrate loading unit including at least one substrate loading plate, on which a substrate is to be loaded;
an injector assembly coupled to the process chamber, the injector assembly configured to supply a plurality of reactants to deposit a multilayer film onto the substrate while sweeping over the substrate loaded on the substrate loading plate;
a plurality of first heat sources configured to heat in a non-contact manner; and
a plurality of second heat sources configured to heat in a contact manner, the first and second heat sources at different positions in the process chamber.

2. The atomic layer deposition apparatus of claim 1, further comprising:
a controller configured to control the first and second heat sources to ensure chemisorption by a self-limiting reaction with respect to each one of the reactants at a respective process temperature thereof.

3. The atomic layer deposition apparatus of claim 2, wherein, when any one of the reactants is supplied into the process chamber, the controller is configured to control the first and second heat sources in real time such that the process temperature in the process chamber corresponds to the process temperature of the reactant supplied into the process chamber.

4. The atomic layer deposition apparatus of claim 1, wherein the substrate loading plate is a plurality of substrate loading plates, and the substrate loading plates are arranged in a vertical direction in the process chamber and are configured to move up and down in the vertical direction in the process chamber.

5. The atomic layer deposition apparatus of claim 4, wherein the first and second heat sources are provided with respect to the substrate loading plates.

6. The atomic layer deposition apparatus of claim 1, wherein
the first heat sources are configured to contact and heat the substrate, and
the second heat sources are adjacent to the first heat sources and configured to heat the substrate in a non-contact manner.

7. The atomic layer deposition apparatus of claim 6, wherein the first heat sources and the second heat sources are configured to be independently controlled.

8. The atomic layer deposition apparatus of claim 6, wherein the first heat sources are heating pads, and each of the heating pads is attached on an upper surface of the substrate loading plate and is configured to directly contact the substrate.

9. The atomic layer deposition apparatus of claim 6, wherein the second heat sources are on at least one side wall surface of the process chamber at an outer area of a circumferential surface of the substrate loading plate.

10. The atomic layer deposition apparatus of claim 9, wherein the second heat sources are symmetrically arranged with respect to the substrate loading plate at the opposite side wall surfaces of the process chamber.

11. The atomic layer deposition apparatus of claim 9, further comprising:
a source accommodation portion on the side wall surface of the process chamber, the source accommodation portion configured to accommodate the second heat sources.

12. The atomic layer deposition apparatus of claim 11, further comprising:
a protection window between the substrate loading unit and the source accommodation portion, the protection window configured to protect the second heat sources; and
a heat reflection mirror provided between the protection window and the side wall surface of the process chamber, the heat reflection mirror configured to reflect heat generated from the second heat sources while maintaining directivity.

13. The atomic layer deposition apparatus of claim 12, wherein the protection window includes a flat surface and the heat reflection mirror includes a curved surface.

14. The atomic layer deposition apparatus of claim 6, wherein the second heat sources are respectively arranged above and parallel to the substrate loading plates

15. The atomic layer deposition apparatus of claim 1, wherein the injector assembly comprises:
a plurality of vertical shafts arranged at respective corner areas of the process chamber, the vertical shafts at diagonal positions forming an operational group;
a plurality of injectors arranged on the vertical shafts, each of the injector arranged at a certain interval along a lengthwise direction of a corresponding one of the vertical shafts and configured to selectively supply the reactants through a plurality of injection holes defined in the injector; and
a plurality of shaft rotation units coupled to the vertical shafts, the shaft rotation unit configured to rotate the vertical shafts.

16. The atomic layer deposition apparatus of claim 15, wherein the injectors are configured to selectively inject the reactants onto the substrate while sweeping over the substrate in association with rotation of corresponding vertical shafts.

17. The atomic layer deposition apparatus of claim 1, further comprising:
a controller configured to control operation of the first and second heat sources based on the reactants supplied to the process chamber.

18. An atomic layer deposition apparatus, comprising:
a plurality of first heat sources and a plurality of second heat sources arranged at various positions in a process chamber, the first heat sources configured to heat at least one substrate in the process chamber in a non-contact manner, and the second heat sources configured to heat the substrate in a contact manner;
an injector assembly configured to selectively supply a reactant from a plurality of reactants to the process chamber; and
a controller configured to control the first and second heat sources based on the supplied reactant.

19. The atomic layer deposition apparatus of claim 18, wherein the injector assembly includes,
a plurality of injectors coupled to a plurality of vertical shafts, each of the injectors arranged at a certain interval along a lengthwise direction of a corresponding one of the vertical shafts and configured to selectively supply the reactants through a plurality of injection holes defined in the injector, and
a plurality of shaft rotation units coupled to the vertical shafts, the shaft rotation units configured to simultaneously rotate an operational group of the injectors by rotating the vertical shafts.

20. The atomic layer deposition apparatus of claim 19, wherein the injector assembly includes a plurality of injectors coupled to a plurality of vertical shafts, each of the injectors configured to selectively inject the reactants onto the substrate while sweeping over the substrate in association with rotation of one of the vertical shafts.
